(19) United States
(12) Patent Application Publication
(10) Pub. No.: US 2002/0180064 A1
(43) Pub. Date: Dec. 5, 2002

(54) Metallized surface wafer level package structure

(75) Inventors: Lu-Chen Hwan, Hsinchu (TW); Fei-Jain Wu, Hsinchu (TW)

Correspondence Address: NIXON PEABODY, LLP, 8180 GREENSBORO DRIVE, SUITE 800, MCLEAN, VA, 22102, US

(73) Assignee: Chipbond Technology Corporation, Hsinchu (TW)

(21) Appl. No.: 10/107,219

(22) Filed: Mar. 28, 2002

(30) Foreign Application Priority Data
Jun. 5, 2001 (TW) 090113553

(51) Int. Cl. H01L 23/495

(52) U.S. Cl. 257/780; 257/668; 257/773

(57) ABSTRACT

The present invention relates to a wafer level package structure with a metal protection layer, and more particularly, to a wafer level package structure with a metal protection layer which is made of titanium, nickel, chromium or alloy thereof. The metal protection layer is adopted to prevent the substrate from being damaged by metal solder bumps. The metal protection layer also contributes to heat conduction and heat dissipation. Moreover, the metal protection layer is acid and alkali resistant and electromagnetic interference (EMI) resistant. The present invention improves the reliability of the IC component effectively.

### BACKGROUND OF THE INVENTION

1. Field of the Invention

The present invention relates to a wafer level package structure with a metal protection layer, and more particularly, to a wafer level package structure with a metal protection layer which is made of titanium (Ti), nickel (Ni), chromium (Cr), Copper (Cu) or alloy thereof.

2. Description of the Prior Art

With the development of very large scale integration (VLSI) and scale-down of the semiconductor device, high demands for the semiconductor package technology increases. Some conventional methods, such as flip-chip packaging technology, are used to reduce the chip size during a packaging process. In the flip-chip packaging method, a ball-grid array is directly formed on the input/output without using wire bonds to connect the device of the integrated circuits (IC) and the lead frames. The metal solder bump of the ball-grid array is typically made of gold (Au), copper (Cu), nickel (Ni), or Sn/Pb alloy.

Please refer to FIG. 1A showing a prior art semiconductor structure 10. The semiconductor structure 10 is located on a silicon substrate 12. An input/output 14 is formed on a surface 16 of the silicon substrate 12, and is electrically connected with an external circuit. The input/output 14 is usually made of conductive materials, such as aluminum (Al). The silicon substrate 12 and the input/output 14 are both covered by a passivation layer 20, and a window 22 is formed above the input/output pad 14 which is not covered by the passivation layer 20. The passivation layer 20 is usually made of oxide, nitride, or organic materials. The passivation layer 20 covers the semiconductor structure 10 so as to protect circuits on the semiconductor structure 10.

An under bump metallurgy layer (UBM layer) 26 is then deposited on a surface 24 of the passivation layer 20 and on a surface 18 of the input/output 14. FIG. 1B shows a method of forming the under bump metallurgy layer 26. The under bump metallurgy layer 26 typically includes an adhesion layer 30 and a wetting layer 28. The adhesion layer 30 is usually made of titanium (Ti), titanium nitride (TiN) or other metal materials. The wetting layer 30 is usually made of copper (Cu), gold (Au) or nickel (Ni). The under bump metallurgy layer 26 is used to improve the connection properties between the input/output 14 and a metal solder bump 40.

As shown in FIG. 1C, a photoresist layer 34 is then deposited on the under bump metallurgy layer 26. The photoresist layer 34 is etched to form a window 38 allowing the metal solder bump 40 to place therein. As shown in FIG. 1D, the metal solder bump 40 is then deposited to cover the window 38, and a protruded mushroom-shape structure is formed on a surface 42 of the photoresist layer 34. Please refer to FIG. 1E, the photoresist layer 34 is then removed by a wet stripping process. As shown in FIG. 1F, the under bump metallurgy layer 26 is removed by a wet stripping process using the metal solder bump 40 as a hard mask. The metal solder bump 40 is then heated to form a ball-shape structure (or is called bump).

The prior art passivation layer 20 is typically made of oxide (such as silicon dioxide (SiO₂)), nitride (such as silicon nitride (Si₃N₄)), or other organic compounds (such as polyimide (PI)), and is used to protect circuits on the semiconductor structure 10. However, due to the limitations of material properties, the materials used to form the prior art passivation layer cannot provide enough protection for the semiconductor devices to prevent from mechanical damages, heat damages, electrostatic discharge (ESD) or electromagnetic interference (EMI) damages.

### SUMMARY OF THE INVENTION

One aspect of the present invention is to provide a wafer level package structure with a metal protection layer so as to solve the prior art problems. The present invention further includes a protection layer located between the passivation layer and the under bump metallurgy layer so as to prevent the substrate from being damaged by metal solder bumps. The protection layer also contributes to heat conduction and heat dissipation. Moreover, the protection layer is acid and alkali resistant, electrostatic discharge (ESD) and electromagnetic interference (EMI) resistant. A preferred material for forming the protection layer is titanium (Ti), nickel (Ni), chromium (Cr),copper (Cu) titanium nitride (TiN), chromium nitride (CrN), nickel nitride (NiN), or alloy thereof.

The present invention can further include an interface layer located between the passivation layer and the protection layer and is used as an adhesion layer or a diffusion barrier. A preferred material for forming the interface layer is titanium (Ti), nickel (Ni), chromium (Cr), copper (Cu), titanium nitride (TiN), chromium nitride (CrN), nickel nitride (NiN), copper nitride (CuN) or alloy thereof.

The protection layer and the interface layer of the present invention can enhance the reliability of the semiconductor devices.

This and other aspects of the present invention will no doubt become obvious to those of ordinary skill in the art after having read the following detailed description of the preferred embodiment which is illustrated in the various figures and drawings.

### BRIEF DESCRIPTION OF THE DRAWINGS

FIG. 1A is a cross-sectional view of a semiconductor substrate, an input/output, and a passivation layer according to the prior art.

FIG. 1B is a cross-sectional view of an under bump metallurgy layer on the semiconductor substrate shown in FIG. 1A.

FIG. 1C is a cross-sectional view of a photoresist layer on the semiconductor substrate shown in FIG. 1B.

FIG. 1D is a cross-sectional view of a metal solder bump covers the window of the under bump metallurgy layer on the semiconductor substrate shown in FIG. 1C.

FIG. 1E is a cross-sectional view of the semiconductor substrate, as shown in FIG. 1D, after removing the photoresist layer.

FIG. 1F is a cross-sectional view of the semiconductor substrate, as shown in FIG. 1E, after etching the under bump metallurgy layer, and heating the metal solder to become a ball-shape.

FIG. 2A is a schematic diagram showing the first embodiment of the wafer level package structure according to the present invention.

FIG. 2B is a schematic diagram showing the second embodiment of the wafer level package structure according to the present invention.

FIG. 2C is a schematic diagram showing the third embodiment of the wafer level package structure according to the present invention.

FIG. 2D is a schematic diagram showing the forth embodiment of the wafer level package structure according to the present invention.

FIG. 2E is a schematic diagram showing the fifth embodiment of the wafer level package structure according to the present invention.

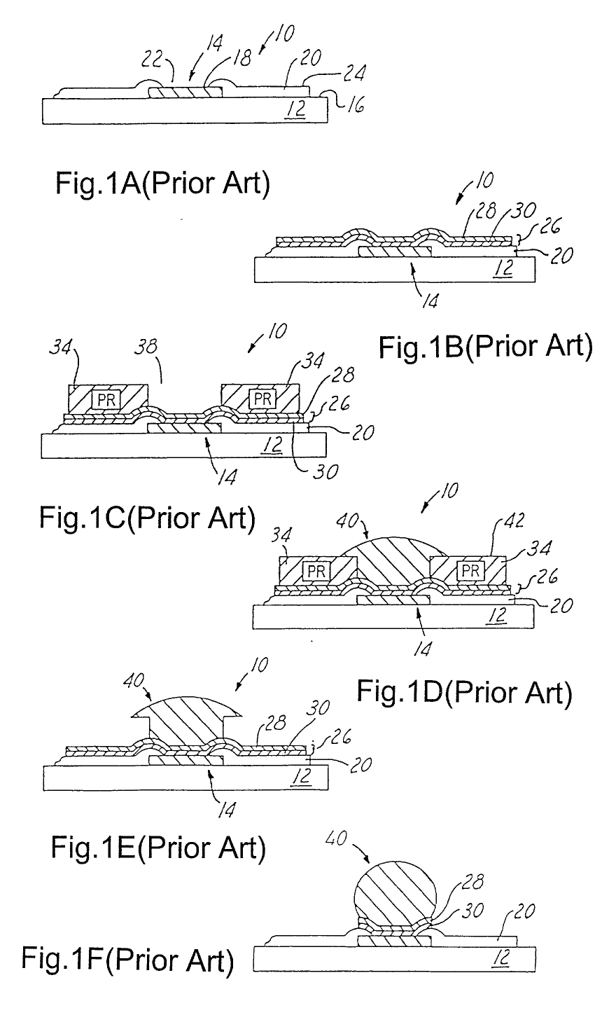

### DETAILED DESCRIPTION OF THE PRESENT INVENTION

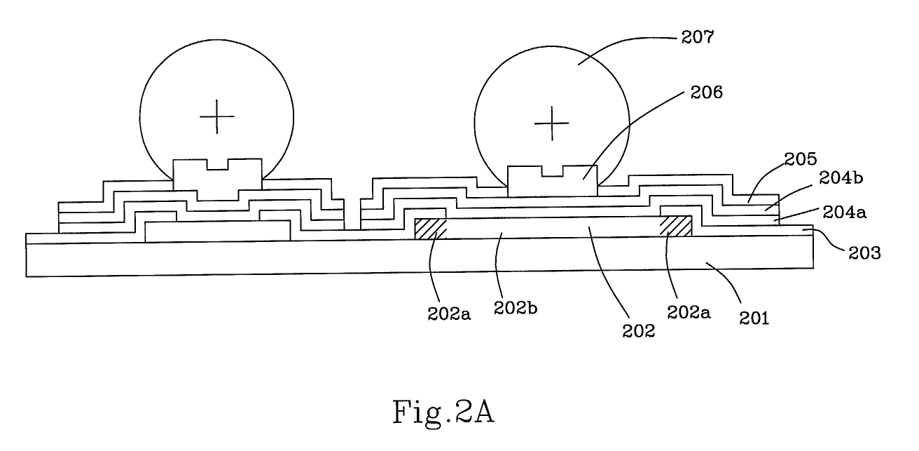

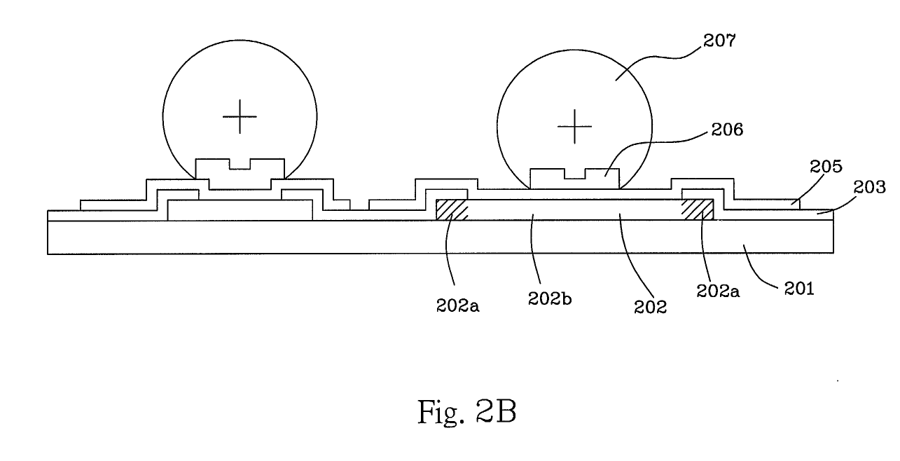

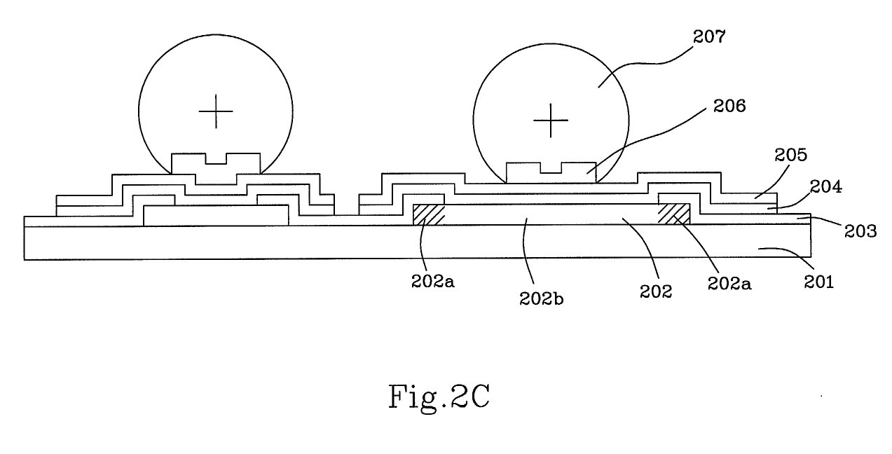

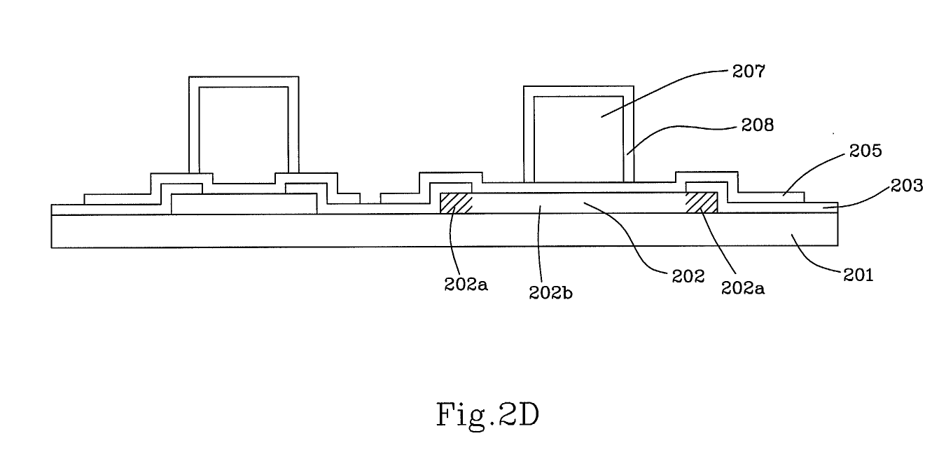

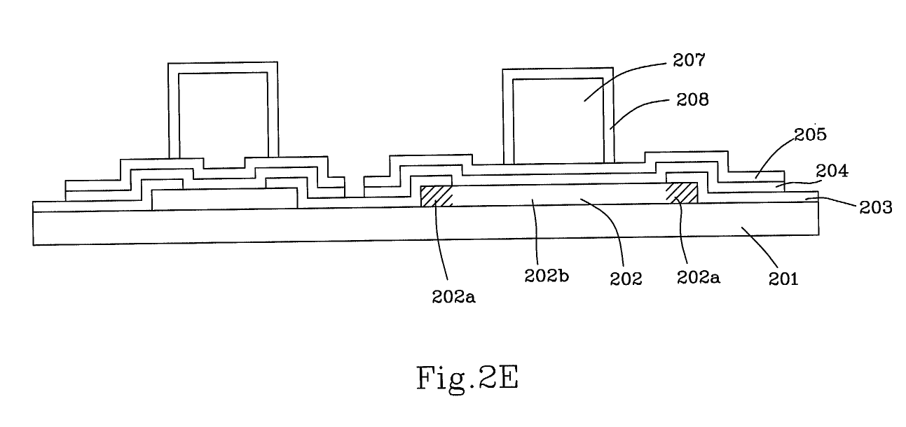

Please refer to FIG. 2A. FIG. 2A is a schematic diagram showing the first embodiment of the wafer level package structure according to the present invention. The first embodiment of the present invention includes a semiconductor substrate 201. A plurality of input/output 202 are disposed on the semiconductor substrate 201, and are used to transmit input or output signals. The input/output 202 are usually made of metal, such as gold (Au), aluminum (Al), or copper (Cu). The semiconductor substrate 201 and the input/output 202 are both covered by a passivation layer 203. The passivation layer 203 is usually made of oxide, (such as silicon dioxide (SiO₂)), nitride (such as silicon nitride (Si₃N₄)), or other organic compounds (such as polyimide (PI)). The passivation layer 203 covers the semiconductor structure so as to protect circuits on the semiconductor structure 201. A window is formed above the second region 202b of the input/output 202 which is not covered the passivation layer 203. In other words, the passivation layer 203 covers the first region 202a of the input/output 202 to avoid the electrically connection between the input/output 202 and an external circuits being isolated.

As shown in FIG. 2A, a first interface layer 204a is deposited to cover the second region 202b of the input/output 202 and the passivation layer 203. The first interface layer 204a is employed as an adhesion layer and diffusion barrier, and is usually made of titanium (Ti), nickel (Ni), chromium (Cr), or metallic nitrides, such as titanium nitride (TiN), chromium nitride (CrN), or nickel nitride (NiN). A second interface layer 204b is then deposited on the first interface layer 204a. The second interface layer is typically made of copper (Cu). In the first embodiment of the present invention, a protection layer 205 is deposited on the second interface layer 204b. The protection layer 205 is usually made of titanium (Ti), nickel (Ni), copper (Cu),chromium (Cr), titanium nitride (TiN), chromium nitride (CrN), nickel nitride (NiN), or alloy, which are heatproof and refractory. The protection layer 205 contributes to heat conduction and heat dissipation. Moreover, the protection layer 205 is acid and alkali resistant, electrostatic discharge (ESD) and electromagnetic interference (EMI) resistant.

As shown in FIG. 2A, an under bump metallurgy layer (UBM layer) 206 is deposited on the protection layer 205 in the first embodiment of the present invention. The under bump metallurgy layer 206 is usually made of copper (Cu), CuNi, gold (Au), or alloy, and is used as an adhesion layer for the metal solder bump. The metal solder bump 207 is located over the under bump metallurgy layer 206, and are usually made of conductive materials which can be used in electroplating technology, such as Sn/Pb alloy, copper (Cu), gold (Au), nickel (Ni), or indium (In).

Please refer to FIG. 2B. FIG. 2B is a schematic diagram showing the second embodiment of the wafer level package structure according to the present invention. The semiconductor substrate 201, the input/output 202, and the passivation layer 203 in the second embodiment are the same as those disclosed in the aforementioned first embodiment, and is not described redundant. As shown in FIG. 2B, a protection layer 205 is directly deposited to cover the second region 202b of the input/output 202 and the passivation layer 203 in the second embodiment. In the second embodiment, the first interface layer 204a and the second interface layer 204b, as shown in FIG. 2A, are not deposed. Similarly, the protection layer 205 is usually made of titanium (Ti), nickel (Ni),copper (Cu), chromium (Cr), titanium nitride (TiN), chromium nitride (CrN), nickel nitride (NiN), or alloy thereof. And the protection layer 205 contributes to heat conduction and heat dissipation. Moreover, the protection layer 205 is acid and alkali resistant, electrostatic discharge (ESD) and electromagnetic interference (EMI) resistant. The same that disclosed in the first embodiment, an under bump metallurgy layer (UBM layer) 206 is deposited on the protection layer 205, and the metal solder bump 207 is located over the under bump metallurgy layer 206.

Please refer to FIG. 2C. FIG. 2C is a schematic diagram showing the third embodiment of the wafer level package structure according to the present invention. The semiconductor substrate 201, the input/output 202, and the passivation layer 203 in the third embodiment are the same as those disclosed in the aforementioned first embodiment, and is not described redundant. As shown in FIG. 2C, an interface layer 204 is deposited to cover the second region 202b of the input/output 202 and the passivation layer 203 in the third embodiment. The interface layer 204 is used as an adhesion layer and diffusion barrier so as to enhance the reliability of the semiconductor package structure. The materials for forming the interface layer 204 are chosen from titanium (Ti), nickel (Ni), chromium (Cr), or metallic nitrides, such as titanium nitride (TiN), chromium nitride (CrN), or nickel nitride (NiN). In the third embodiment, the protection layer 205 is deposited on the interface layer 204. The protection layer 205 is usually made of titanium (Ti), nickel (Ni), copper (Cu), chromium (Cr), titanium nitride (TiN), chromium nitride (CrN), nickel nitride (NiN), or alloy thereof. And the protection layer 205 contributes to heat conduction and heat dissipation. Moreover, the protection layer 205 is acid and alkali resistant, electrostatic discharge (ESD) and electromagnetic interference (EMI) resistant. The same as that disclosed in the first embodiment, an under bump metallurgy layer (UBM layer) 206 is deposited on the protection layer 205, and the metal solder bump 207 is located over the under bump metallurgy layer 206.

Please refer to FIG. 2D. FIG. 2D is a schematic diagram showing the forth embodiment of the wafer level package structure according to the present invention. The semiconductor substrate 201, the input/output 202, and the passivation layer 203 in the forth embodiment are the same as those disclosed in the aforementioned first embodiment, and is not described redundant. As shown in FIG. 2D, a protection layer 205 is directly deposited to cover the second region 202b of the input/output 202 and the passivation layer 203 in the forth embodiment. The interface layer 204, as shown in FIG. 2C,is not deposited. Similarly, the protection layer 205 is usually made of titanium (Ti), nickel (Ni), copper (Cu), chromium (Cr), or metallic nitrides, such as titanium nitride (TiN), chromium nitride (CrN), or nickel nitride (NiN). The protection layer 205 contributes to heat conduction and heat dissipation. Moreover, the protection layer 205 is acid and alkali resistant, electrostatic discharge (ESD) and electromagnetic interference (EMI) resistant. Different from that disclosed in the aforementioned embodiments, the metal solder bump 207 is directly located over the protection layer 205 without depositing an under bump metallurgy layer (UBM layer). The metal solder bump 207 of the forth embodiment is surrounded by a combination layer 208. The combination layer 208 is a thin film metal layer, and is adopted to protect the metal solder bump 207, or is used to combine devices. The combination layer is usually made of tin (Sn), Sn/Pb alloy, gold (Au), or silver (Ag). Both the type and the package structure of the metal solder bump in this embodiment are different from those in the aforementioned embodiments. Thus, the shapes of the metal solder bump is not deformed while combing to other devices.

Please refer to FIG. 2E. FIG. 2E is a schematic diagram showing the fifth embodiment of the wafer level package structure according to the present invention. The semiconductor substrate 201, the input/output 202, and the passivation layer 203 in the fifth embodiment are the same as those disclosed in the aforementioned first embodiment, and is not described redundant. As shown in FIG. 2E, an interface layer 204 is deposited to cover the second region 202b of the input/output 202 and the passivation layer 203 in the fifth embodiment. The interface layer 204 is employed as an adhesion layer and a diffusion barrier so as to enhance the reliability of the semiconductor package structure. The materials for forming the interface layer 204 are chosen from titanium (Ti), nickel (Ni), chromium (Cr), or metallic nitrides, such as titanium nitride (TiN), chromium nitride (CrN), or nickel nitride (NiN). In the fifth embodiment, the protection layer 205 is deposited on the interface layer 204. The protection layer 205 is usually made of titanium (Ti), nickel (Ni), copper (Cu), chromium (Cr), or metallic nitrides, such as titanium nitride (TiN), chromium nitride (CrN), or nickel nitride (NiN). The protection layer 205 contributes to heat conduction and heat dissipation. Moreover, the protection layer 205 is acid and alkali resistant, electrostatic discharge (ESD) and electromagnetic interference (EMI) resistant. The metal solder bump 207 used in the fifth embodiment is the same as that disclosed in the forth embodiment. The metal solder bump 207 is directly located over the protection layer 205 without depositing an under bump metallurgy layer (UBM layer). The same as that in the forth embodiment, the metal solder bump 207 of the fifth embodiment is surrounded by a combination layer 208. The combination layer 208 is a thin film metal layer, and is used to protect the metal solder bump 207, or is used to combine devices. The combination layer is usually made of tin (Sn), Sn/Pb alloy, gold (Au), or silver (Ag).

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A wafer level package structure comprising:
a semiconductor substrate;
an input/output located over the semiconductor substrate, the input/output comprising a first region and a second region;
a passivation layer located over the first region of the input/output and over the semiconductor substrate;
a protection layer located over the second region of the input/output and over the passivation layer;
an under bump metallurgy layer located over the protection layer; and
at least one metal solder bump located over the under bump metallurgy layer.

2. The wafer level package structure of claim 1, wherein a material of the input/output is selected from a group consisting of gold (Au), aluminum (Al), and copper (Cu).

3. The wafer level package structure of claim 1, wherein a material of the passivation layer is selected from a group consisting of silicon nitride (Si₃N₄), silicon dioxide (SiO₂), benzocyclobutene (BCB), and polyimide (PI).

4. The wafer level package structure of claim 1, wherein a material of the protection layer is selected from a group consisting of titanium (Ti), nickel (Ni), copper (Cu), chromium (Cr), titanium nitride (TiN), nickel nitride (NiN), chromium nitride (CrN), and alloy thereof.

5. The wafer level package structure of claim 1, wherein a material of the under bump metallurgy layer is selected from a group consisting of copper (Cu), CuNi, gold (Au), and alloy thereof.

6. The wafer level package structure of claim 1, wherein a material of the metal solder bump is selected from a group consisting of Sn/Pb alloy, copper (Cu), gold (Au), nickel (Ni), and indium (In).

7. A wafer level package structure comprising:
a semiconductor substrate;
an input/output located over the semiconductor substrate, the input/output comprising a first region and a second region;
a passivation layer located over the first region of the input/output and on the semiconductor substrate;
an interface layer located over the second region of the input/output and on the passivation layer;
a protection layer located over the interface layer;
an under bump metallurgy layer located over the protection layer; and
at least one metal solder bump located over the under bump metallurgy layer.

8. The wafer level package structure of claim 7, wherein the interface layer is made of metal and metallic nitride.

9. The wafer level package structure of claim 7, wherein a material of the interface layer is selected from a group consisting of titanium (Ti), titanium nitride (TiN), nickel (Ni), nickel nitride (NiN), chromium (Cr), chromium nitride (CrN), and alloy thereof.

10. A wafer level package structure comprising:
a semiconductor substrate;
an input/output located over the semiconductor substrate, the input/output comprising a first region and a second region;
a passivation layer located over the first region of the input/output and over the semiconductor substrate;
a first interface layer located over the second region of the input/output and over the passivation layer;
a second interface layer located over the first interface layer;
a protection layer located over the second interface layer;
an under bump metallurgy layer located over the protection layer; and
at least one metal solder bump located over the under bump metallurgy layer.

11. The wafer level package structure of claim 10, wherein the first interface layer is made of metal and metallic nitride.

12. The wafer level package structure of claim 10, wherein a material of the first interface layer is selected from a group consisting of titanium (Ti), titanium nitride (TiN), chromium (Cr), chromium nitride (CrN), nickel (Ni), nickel nitride (NiN), and alloy thereof.

13. The wafer level package structure of claim 10, wherein the second interface layer is made of copper (Cu).

14. A wafer level package structure comprising:
a semiconductor substrate;
an input/output located over the semiconductor substrate, the
input/output comprising a first region and a second region;
a passivation layer located over the first region of the input/output and over the semiconductor substrate;
a protection layer first located over the second region of the input/output and over the passivation layer;
at least one metal solder bump located over the protection layer; and
a combination layer surrounding the metal solder bump.

15. The wafer level package structure of claim 14, wherein a material of the protection layer is selected from a group consisting of titanium (Ti), nickel (Ni), copper (Cu), chromium (Cr), titanium nitride (TiN), nickel nitride (NiN), chromium nitride (CrN), and alloy thereof.

16. The wafer level package structure of claim 14, wherein the metal solder bump is selected from a group consisting of Sn/Pb alloy, copper (Cu), gold (Au), nickel (Ni), and indium (In).

17. The wafer level package structure of claim 14, wherein a material of the combination layer is selected from a group consisting of tin (Sn), Sn/Pb alloy, gold (Au), and silver (Ag).

18. A wafer level package structure comprising:
a semiconductor substrate;
an input/output located over the semiconductor substrate, the input/output comprising a first region and a second region;
a passivation layer located over the first region of the input/output and over the semiconductor substrate;
an interface layer located over the second region of the input/output and over the passivation layer;
a protection layer located over the interface layer;
at least one metal solder bump located over the protection layer; and
a combination layer surrounding the metal solder bump.

19. The wafer level package structure of claim 18, wherein the interface layer is made of metal and metallic nitride.

20. The wafer level package structure of claim 18, wherein a material of the interface layer is selected from a group consisting of titanium (Ti) titanium nitride (TiN), chromium (Cr), chromium nitride (CrN), nickel (Ni), nickel nitride (NiN), and alloy thereof.

21. The wafer level package structure of claim 18, wherein a material of the protection layer is selected from a group consisting of titanium (Ti), nickel (Ni), copper (Cu), chromium (Cr), titanium nitride (TiN), nickel nitride (NiN), chromium nitride (CrN), and alloy thereof.

22. The wafer level package structure of claim 18, wherein a material of the metal solder bump is selected from a group consisting of Sn/Pb alloy, copper (Cu), gold (Au), nickel (Ni), and indium (In).

23. The wafer level package structure of claim 18, wherein a material of the combination layer is selected from a group consisting of tin (Sn), Sn/Pb alloy, gold (Au), o r silver (Ag).
